(19) United States
(12) Patent Application Publication
(10) Pub. No.: US 2009/0026620 A1
(43) Pub. Date: Jan. 29, 2009

(54) METHOD FOR CUTTING MULTILAYER SUBSTRATE, METHOD FOR MANUFACTURING SEMICONDUCTOR DEVICE, SEMICONDUCTOR DEVICE, LIGHT EMITTING DEVICE, AND BACKLIGHT DEVICE

(75) Inventor: Kiyohisa OHTA, Mihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/119,920

(22) Filed: May 13, 2008

(30) Foreign Application Priority Data
May 15, 2007 (JP) 2007-129791

(51) Int. Cl. B26D 3/06; H01L 21/302; H05K 1/00; H01L 23/00

(52) U.S. Cl. 257/758; 83/875; 438/460; 174/250; 257/E23.001; 257/E21.214

(57) ABSTRACT

In order to cut off, without causing any burr, a multilayer substrate having a metal layer on a front surface and a second metal layer on a back surface, a method for cutting the multilayer substrate is a method for cutting the multilayer substrate having a metal layer on the front surface and a backside electrode on the back surface, the method including the step of cutting the multilayer substrate into certain depth respectively from a metal layer side and from a backside electrode side, width of a notch on the metal layer side and width of a notch on the backside electrode side being different from each other.

This Nonprovisional application claims priority under 35 U.S.C. § 119(a) on Patent Application No. 129791/2007 filed in Japan on May 15, 2007, the entire contents of which are hereby incorporated by reference.

### FIELD OF THE INVENTION

The present invention relates to a method for cutting a multilayer substrate having a first metal layer on a front surface and a second metal layer on a back surface, a method for manufacturing a semiconductor device equipped with this multilayer substrate, a semiconductor device, a light emitting device, and a backlight device.

### BACKGROUND OF THE INVENTION

A conventional method for cutting a multilayer substrate is described below. FIGS. 8 (a) to 8 (c) are cross-sectional views for describing a conventional method for cutting a multilayer substrate. A conducting section for electrolysis plating 73 interconnects a conducting section 71, which is connected to an outer line of an insulating substrate 75, with a conducting section 72, which is independent from the outer line. After forming a kerf 74 on the conducting section 73 in advance, as shown in FIG. 8 (b), a recess section 76 is formed on the insulating substrate 75 by a counterbore forming process or the like, as shown in FIG. 8 (c). Then, the conducting section 73 is cut through.

FIGS. 9(a) and 9(b) are cross-sectional views for describing another conventional method for cutting the multilayer substrate. A plurality of metalized layers 62 are formed on a principle surface 61a of a substrate 61. The metalized layers 62 are separated into individual pieces by un-metalized sections 63, which are exposed parts of the surface of the substrate 61. The un-metalized sections 63 serve as kerfs for facilitating the cutting of the substrate and are set equal to or wider than width of a cutter to be used. Then, the substrate 61 is set on a precision cutter or the like (not illustrated), and is cut off, with a diamond cutter 64 or the like, a peripheral cutting edge of which is narrower than width of the un-metalized sections 63, along the kerfs of the un-metalized sections 63 into desired sizes of circuit substrates.

FIGS. 10 (a) and 10 (b) are cross-sectional views for describing yet another conventional method for cutting a multilayer substrate. A surface-mounted LED substrate forms a resist film at least on a part of the conduction pattern, the part to be cut by dicing, on the back surface of the multi-faced LED so as to cover the conduction pattern. Thus, even if a dicing blade dices the multi-faced LED, as shown in FIG. 10(a), burrs of the conduction pattern are overbore by the resist layer covering the conduction pattern, as shown in FIG. 10(b). Therefore, the burrs of the conduction pattern do not stick out from the resist layer.

Next, the following description describes an example of cutting out a light emitting device from a multilayer substrate including a thick film metal layer, a multilayer wiring resin layer, and a glass epoxy-substrate, and a backside electrode layer. FIG. 11(a) is a plan view for showing yet another conventional method for cutting the multilayer substrate while FIG. 11(b) is a cross-sectional view taken along the plane AA of FIG. 11(a). In a manufacturing method for a semiconductor element or a light emitting device equipped with a multilayer substrate having wiring in or on an insulating substrate made of ceramics or resin, there are various problems in a process of cutting the multilayer substrate and separating it into individual pieces.

A light emitting device material 89 includes a glass epoxy-substrate 81, on top of which a multilayer wiring resin layer 80 is formed. The multilayer wiring resin layer 80 includes a wiring layer 88 and a resin layer 87. A thick film metal layer 93 is formed on top of the resin layer 87. A backside electrode 94 is formed on the other side of the multilayer wiring resin layer 80 with the glass epoxy-substrate 81 therebetween. The wiring layer 88 and the backside electrode 94 are electrically interconnected by plating in a through-hole formed within the glass epoxy-substrate 81.

A cup-shaped recess section 99 is formed in a thick film metal layer 93. An internal part of the recess section 99 is etched and an LED chip loading surface 86 of the resin layer 87 is exposed at the bottom of the recess section 99. Neither an LED chip loaded on the LED chip loading surface 86 nor sealing resin for sealing the LED chip in the recess section 99 is illustrated in figures. An internal wall of the recess section 99 is a reflective surface encircling the LED chip. Such recess sections are arranged on a grid, and un-processed parts between the recess sections are to be cut. Usually, dicing of the glass epoxy-substrate is performed by cutting from the thick film metal layer 93, with a blade referred to as an electrocast blade, which is covered with a diamond particle.

The conventional art described above is disclosed in Japanese Unexamined Patent Application Publication No. 03-183190 (date of publication on Aug. 9, 1991), Japanese Unexamined Patent Application Publication No. 03-259589 (date of publication on Nov. 19, 1991), and Japanese Unexamined Patent Application Publication No. 2007-88155 (date of publication on Apr. 5, 2007), for example.

However, the conventional art described with FIGS. 11(a) and 11(b) involves a problem that on the cross-section, burrs are caused on the backside electrode 94. In addition, there is a problem that it is difficult to cut off the multilayer substrate since: scraps cut are produced during dicing the thick film metal layer 93; and the blade wastes significantly. If the blade is replaced with a blade referred to as a carbide blade, which is made of tungsten carbide and has a saw edged shape, the metal layer is fully diced easily. However, this configuration involves a problem that cracks are formed in the multilayer wiring resin layer 80.

Besides, though cracks are not formed much on the multilayer wiring resin layer 80 when the metal layer is diced, with the electrocast blade, from the backside electrode 94, there is a problem that the burrs of the metal layer are caused in an upper part of the thick film metal layer 93.

Since this light emitting device uses the cross section as an implementing surface, there arises a problem that the burrs of the metal layer interfere with implementation. Furthermore, there is a problem that the burrs of the metal layer become dust, then become short cut actors. Degrees of hardness of the material are as follows: the thick film metal layer=the back surface electrode<the glass epoxy-substrate=the multilayer wiring resin layer. That is to say, the degrees of hardness of the thick film metal layer 93 and the backside electrode 94 are smaller than the degrees of hardness of the glass epoxy-substrate 81 and the multilayer wiring resin layer 80. The thick film metal layer 93 and the backside electrode 94 have the degrees of hardness substantially equal with each other while the glass epoxy-substrate 81 and the multilayer wiring resin layer 80 have the degrees of hardness substantially equal with each other.

The configurations shown in FIGS. 8(a) to 10(b) describe the method for cutting the substrates such as those having the metal layers on one surfaces only. Thus, the configurations do not indicate the present invention, which cuts substrates having metal layers on both surfaces.

As described above, the configuration described with FIGS. 11(a) and 11(b) involves the problems that since an adhesive sheet for holding the multilayer substrate which is to be cut off is soft, burrs are formed on the metal layer (the thick film layer, the backside electrode layer, and the like) when the layer is cut off; that when the metal layer is cut, cutting efficiency is lowered due to cut scraps and the blade wastes according to the compatibility between the material and the blade as well as the compatibility with the cutting method; and that when the lamination configuration including a layer of the resin material is cut, cracks are formed on the resin layer unless selection of the blade and a cutting manner are devised.

### SUMMARY OF THE INVENTION

The present invention is made in the view of the problems, and an object of the present invention is to realize: a method capable of cutting a multilayer substrate without causing any burr, a multilayer substrate which has a first metal layer on a front surface and a second metal layer on a back surface; a method for manufacturing a semiconductor device; a semiconductor device; a light emitting device; and a backlight device.

In order to attain the object, a cutting method of the present invention, the method for cutting a multilayer substrate, is a method for cutting a multilayer substrate having a first metal layer on a front surface and a second metal layer on a back surface and includes a step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, and width of a kerf on the first metal layer and width of a kerf on the second metal layer are different from each other.

According to these characteristics, the multilayer substrate is cut into certain depth from the first metal layer side, and is cut into certain depth from the second metal layer side. Thus, the first metal layer is not cut off, from the second metal layer side, to the other side of the multilayer substrate; therefore, burrs are not formed on the first metal layer. In addition, since the second metal layer is not cut off, from the first metal layer side, to the other side of the multilayer substrate, burrs are not formed on the second metal layer. Consequently, it is possible to cut off, without causing any burrs, the multilayer substrate having the first metal layer on the front surface and the second metal layer on the back surface. Besides, since width of the kerf on the first metal layer and width of the kerf on the second metal layer are different from each other, it is possible to standardize a form of a cross section after cutting.

In order to attain the object, a manufacturing method of the present invention, the method for manufacturing a semiconductor device, is a method for manufacturing a semiconductor device equipped with the multilayer substrate having the first metal layer on the front surface and the second metal layer on the back surface and includes a step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, and width of the kerf on the first metal layer and width of the kerf on the second metal layer are different from each other.

According to these characteristics, the multilayer substrate is cut into certain depth from the first metal layer side, and is cut into certain depth from the second metal layer side. Thus, the first metal layer is not cut off, from the second metal layer side, to the other side of the multilayer substrate; therefore, burrs are not formed on the first metal layer. In addition, since the second metal layer is not cut off, from the first metal layer side, to the other side of the multilayer substrate, burrs are not formed on the second metal layer. Consequently, it is possible to cut off, without causing any burrs, the multilayer substrate having the first metal layer on the front surface and the second metal layer on the back surface. Besides, since width of the kerf on the first metal layer and width of the kerf on the second metal layer are different from each other, it is possible to standardize the form of the cross section after cutting.

In order to attain the object, a semiconductor device of the present invention is manufactured through a method for manufacturing a semiconductor device equipped with the multilayer substrate having the first metal layer on the front surface and the second metal layer on the back surface, the manufacturing method including a step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, width of the kerf on the first metal layer and width of the kerf on the second metal layer being different from each other.

According to these characteristics, the multilayer substrate is cut into certain depth from the first metal layer side, and is cut into certain depth from the second metal layer side. Thus, the first metal layer is not cut off, from the second metal layer side, to the other side of the multilayer substrate; therefore, burrs are not formed on the first metal layer. In addition, since the second metal layer is not cut off, from the first metal layer side, to the other side of the multilayer substrate, burrs are not formed on the second metal layer. Consequently, it is possible to cut off, without causing any burrs, the multilayer substrate having the first metal layer on the front surface and the second metal layer on the back surface. Besides, since width of the kerf on the first metal layer and width of the kerf on the second metal layer are different from each other, it is possible to standardize the form of the cross section after cutting.

In order to attain the object, a light emitting device of the present invention is a light emitting device equipped with the multilayer substrate having the first metal layer on the front surface and the second metal layer on the back surface; has the cup-shaped recess section, on the first metal layer, provided with a light emitting element; is manufactured through the manufacturing method including the step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, width of the kerf on the first metal layer and width of the kerf on second metal layer being different from each other; and has a step at a position on the cross section of the multilayer substrate, where the kerfs from the first metal layer side and the second metal layer side meet each other.

According to these characteristics, the multilayer substrate is cut into certain depth from the first metal layer side, and is cut into certain depth from the second metal layer side. Thus, the first metal layer is not cut off, from the second metal layer side, to the other side of the multilayer substrate; therefore, burrs are not formed on the first metal layer. In addition, since the second metal layer is not cut off, from the first metal layer side, to the other side of the multilayer substrate, burrs are not formed on the second metal layer. Consequently, it is possible to cut off, without causing any burrs, the multilayer substrate having the first metal layer on the front surface and the second metal layer on the back surface. Besides, since width of the kerf on the first metal layer and width of the kerf on the second metal layer are different from each other, it is possible to standardize the form of the cross section after cutting.

In order to attain the object, a backlight device of the present invention includes the light emitting device, a reflective sheet, and an optical waveguide. The light emitting device is equipped with the multilayer substrate having the first metal layer on the front surface and the second metal layer on the back surface; includes the cup-shaped recess section, on the first metal layer, provided with the light emitting element; is manufactured through the manufacturing method including the step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, width of the kerf on the first metal layer and width of the kerf on second metal layer being different from each other; and has the step at the position on the cross section of the multilayer substrate, where the kerfs from the first metal layer side and the second metal layer side meet each other. The reflective sheet is implemented, on the cross section of the multilayer substrate provided to the light emitting device, with the light emitting device. The optical waveguide irradiates a liquid crystal panel with light emitted from the light emitting device, by scattering the light.

According to these characteristics, the multilayer substrate is manufactured by being cut into certain depth from the first metal layer side, and being cut into certain depth from the second metal layer side. Thus, the first metal layer is not cut off, from the second metal layer side, to the other side of the multilayer substrate; therefore, burrs are not formed on the first metal layer. In addition, since the second metal layer is not cut off, from the first metal layer side, to the other side of the multilayer substrate, burrs are not formed on the second metal layer. Consequently, it is possible to cut off, without causing any burrs, the multilayer substrate having the first metal layer on the front surface and the second metal layer on the back surface. Besides, since width of the kerf on the first metal layer and width of the kerf on the second metal layer are different from each other, it is possible to standardize the form of the cross section after cutting.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a perspective view, showing an outer appearance of light emitting device material of the present embodiment.

FIG. 2 (a) is a plan view for describing a configuration of the light emitting device material while FIG. 2 (b) is a cross-sectional view taken along the cross section AA of FIG. 2(a).

FIGS. 3(a) to 3(d) are cross-sectional views for describing the method for cutting the multilayer substrate provided to the light emitting device material.

FIG. 4 is a cross-sectional view, showing the configuration of the light emitting device manufactured through the method for cutting the multilayer substrate.

FIG. 5 is a perspective view, showing an outer appearance of the light emitting device.

FIGS. 6(a) to 6(c) are cross-sectional views for describing another method for cutting the multilayer substrate.

FIG. 7 is a cross-sectional view, showing the configuration of the light emitting device manufactured through another method for cutting the multilayer substrate.

FIGS. 8(a) to 8(c) are cross sectional views for describing the conventional method for cutting the multilayer substrate.

FIGS. 9(a) and 9(b) are cross-sectional views for describing another conventional method for cutting the multilayer substrate.

FIGS. 10(a) and 10(b) are cross-sectional views for describing yet another conventional method for cutting the multilayer substrate.

FIG. 11(a) is a plan view for describing still another conventional method for cutting the multilayer substrate while FIG. 11(b) is a cross-sectional view taken along the cross section AA of FIG. 11(a).

### DESCRIPTION OF THE EMBODIMENTS

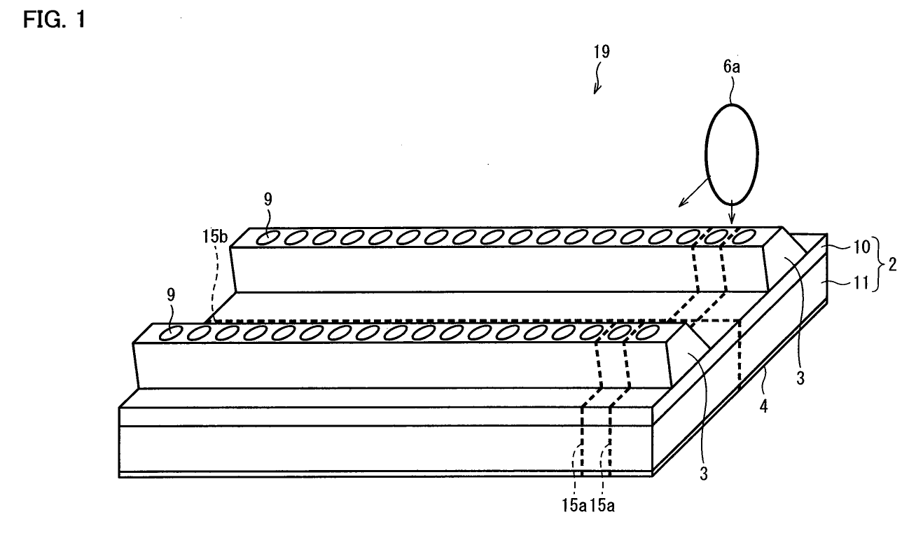

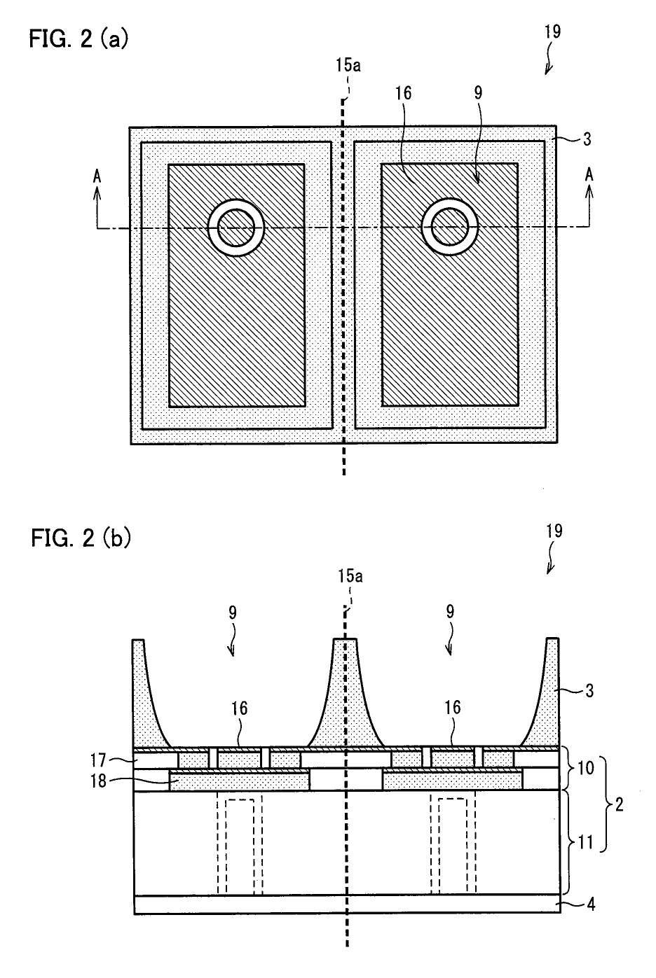

One embodiment of the present invention is described as below, referring to FIGS. 1 to 7. FIG. 1 is the perspective view, showing an outer appearance of light emitting device material 19 of the present embodiment. FIG. 2(a) is the plan view for describing the configuration of the light emitting device material 19 while FIG. 2(b) is the cross-sectional view taken along the cross section AA of FIG. 2(a). The light emitting device material 19 includes a multilayer substrate 2, and the multilayer substrate 2 includes a glass epoxy-substrate 11. On top of the glass epoxy-substrate 11, a multilayer wiring resin layer 10 is formed. The multilayer wiring resin layer 10 includes a wiring layer 18 and a resin layer 17. On top of the resin layer 17, a plurality of stripe-shaped thick film metal layers 3 are arranged parallel to each other at regular intervals. A backside electrode 4 is formed on the other side of the multilayer wiring resin layer 10 with the glass epoxy-substrate 11 therebetween. Plating in a though-hole formed within the glass epoxy-substrate 11 electrically connects the wiring layer 18 with the backside electrode 4.

On surface of the thick film metal layers 3, a plurality of cup-shaped recess sections 9 are formed at regular intervals. Inner parts of the recess sections 9 are etched, and LED chip loading surfaces 16 of the resin layer 17 are exposed at the bottom of the recess sections 9. Neither the LED chips loaded on the LED loading surfaces 16 nor sealing resin for sealing the LED chips in the recess sections 9 is illustrated. Inner walls of the recess sections 9 are reflective surfaces encircling the LED chips. Such recess sections 9 are arranged in a matrix, as shown in FIG. 1. The light emitting device material 19 is cut between the metal layers formed in the striped-form, by displacing along a dashed line 15b a rotating electrocast blade 6a relatively to the material of the light emitting device 19; and also the light emitting device material 19 is cut via the metal layer 3 between the recess sections 9, by displacing along dashed lines 15a the rotating blade 6a relatively to the light emitting device material 19. A diameter of the electrocast blade 6a is about 2 to 3 inches and its width is from tens of μm to hundreds of μm, for example. The rim of the electrocast blade 6a is coated with particulate diamonds. The light emitting device material 19 is cut out with the electrocast blade 6a while end face of the device material serves as a reference point for cutting. By cutting the end surface as the reference point, dimension accuracy can be enhanced.

Besides, it is possible to enhance the dimension accuracy by forming a through-hole in an end part of the light emitting device material 19, and perceiving, by a monitor, the hole on the front side or on the back side so as to use it as the reference point. In the case described above and in this case, a distance between the through-hole or the end surface to a reflector cutting part of the nearest cup-shaped recess section 9 is measured on the front surface first, and modifying this distance part from the through-hole or from the end surface before cutting the back side at a prescribed pitch. Yet, there is still some margin of error between cutting positions on the front side and the back side due to margin of error caused in perception, by the monitor for cutting, of the centers of the through-hole and the cutting position.

In order to eliminate the margins of error, of the plurality of the cup-shaped recess sections 9, the glass epoxy-substrate is taken out from the recess section 9 disposed endmost on the material of the light emitting device 19; the LED chip loading surface is used for the perception by the monitor for cutting; a design value of the distance between the loading surface and the reflector cutting part is used; and the light emitting device material 19 is cut off.

Manufacturing accuracy to this design value is determined through a process of manufacturing the multilayer wiring resin layer, and the manufacturing accuracy is higher, as compared to the accuracy of measuring the distance; therefore, the dimension accuracy can be enhanced more.

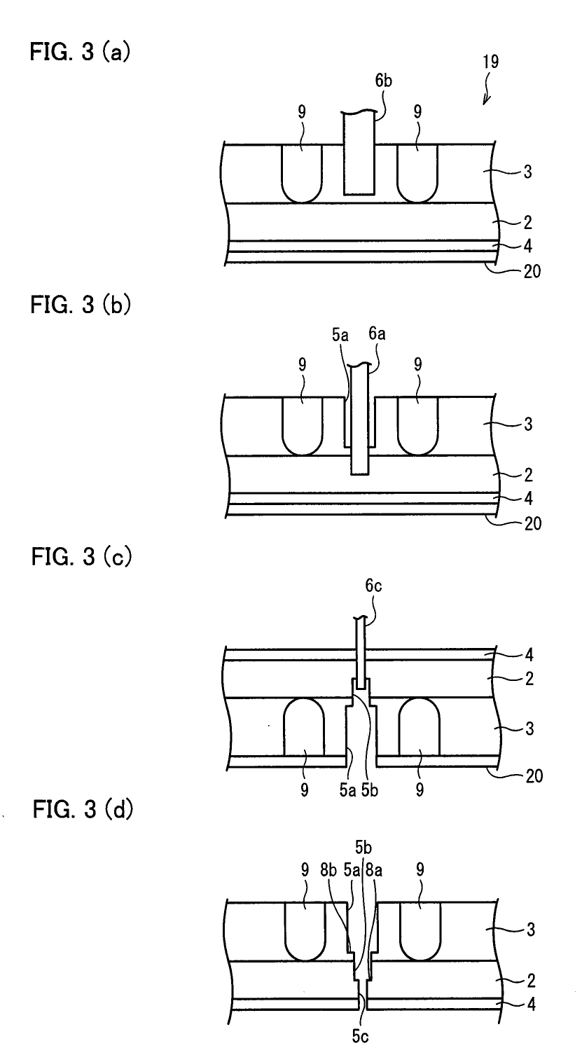

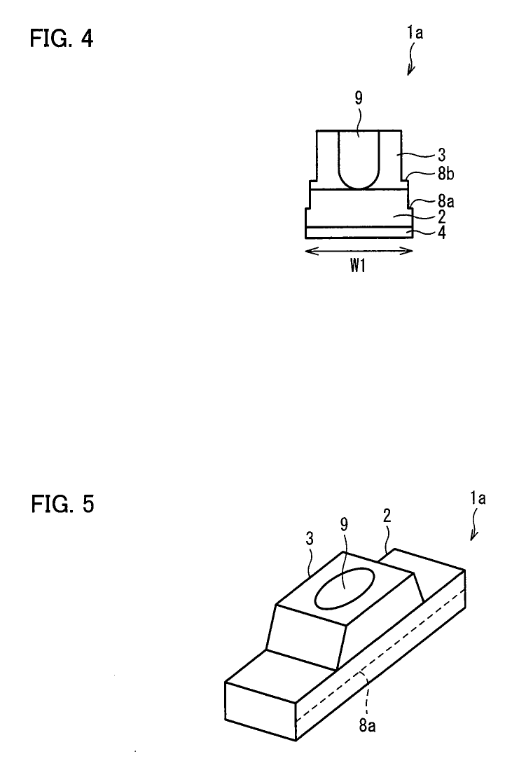

FIGS. 3(a) to 3(d) are cross-sectional views for describing the method for cutting the multilayer substrate provided to the light emitting device material 19. FIG. 4 is a cross-sectional view, showing a configuration of a light emitting device 1a manufactured in the method for cutting the multilayer substrate. FIG. 5 is a perspective view, showing the outer appearance of the light emitting device 1a.

As illustrated in FIG. 3(a), the light emitting device material 19 is firmly held first by using an adhesive sheet 20 applied to the backside electrode 4. Then, a cutting trench 5a (FIG. 3(b)) is formed by cutting, with the carbide blade 6b, from the surface of the metal layer 3 between the recess sections 9 to right before an interface between the metal layer 3 and the multilayer substrate 2. The carbide blade 6b is made of cemented carbide and has an ungula-shaped saw blade on its rim. The cemented carbide includes tungsten carbide and Cobalt. Metal can be cut suitably with the cemented carbide blade 6b.

As illustrated in FIG. 3(b), an electrocast blade 6a, which is thinner than the carbide blade 6b, then cuts the rest of the metal layer 3, and further cuts the multilayer substrate 2 into certain depth so as to form a cutting trench 5b (FIG. 3(c)).

As illustrated in FIGS. 3(c), 3(d), 4, and 5, the adhesive sheet 20 is peeled away from the backside electrode 4, then the light emitting device material 19 is inverted, and an adhesive sheet 20 is applied to the surface of the metal layer 3 so as to hold the device material. After that, an electrocast blade 6c, which is thinner than the electrocast blade 6a, cuts the backside electrode 4 and the multilayer substrate 2 so as to form a cutting trench 5c reaching to the cutting trench 5b. A step 8b is formed on the cross section of the metal layer 3 between the cutting trench 5a and the cutting trench 5b while a step 8a is formed on the cross section of the multilayer substrate 2 between the cutting trench 5b and the cutting trench 5c. Like this, the cutting trench 5a is formed on the metal layer 3, the cutting trench 5b is formed over the metal layer 3 and the multilayer substrate 2, and the cutting trench 5c is formed from the multilayer substrate 2 through the backside electrode 4. Width of the cutting trench 5a is wider than width of the cutting trench 5b while width of the cutting trench 5b is wider than width of the cutting trench 5c. The light emitting device 1a is manufactured in this way. Width dimension W1 of the light emitting device 1a is from 3 mm to 5 mm, for example.

The metal layer 3 (metal reflector) of the light emitting device 1a manufactured in the above manner includes either anode potential or cathode potential of the LED chip, the chip provided in the recess section 9 yet not illustrated. The light emitting device 1a is implemented on its cross section to the reflective sheet of the backlight device. Since the steps 8a and 8b are formed on the cross section, as shown in FIG. 4, the cross section of the metal layer 3 (metal reflector) and the implementing surface of the reflective sheet do not touch each other while the glass epoxy-substrate of the multilayer substrate 2 touches the implementing surface of the reflective sheet.

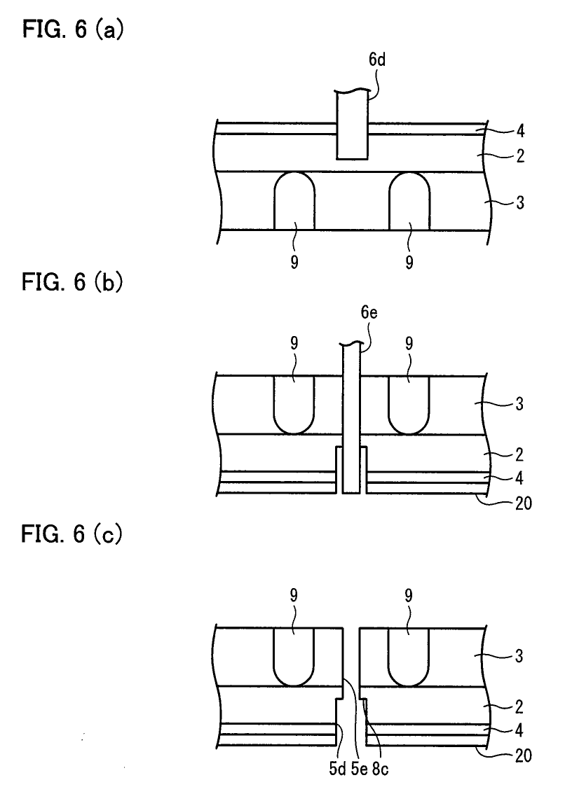

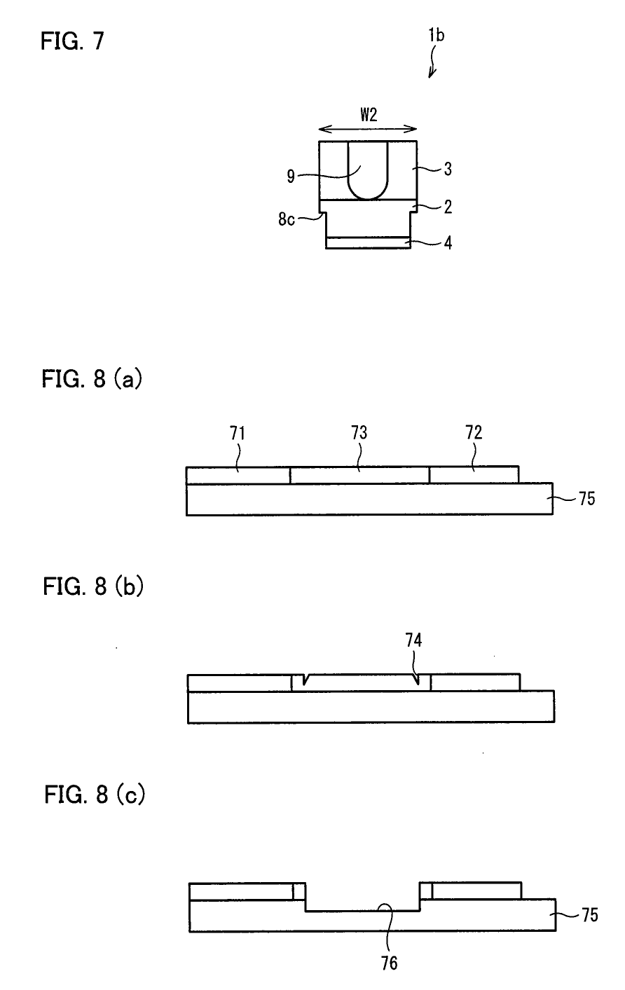

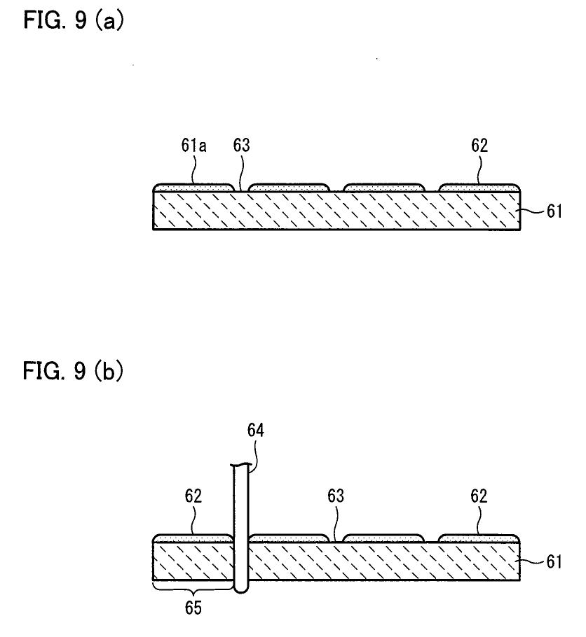

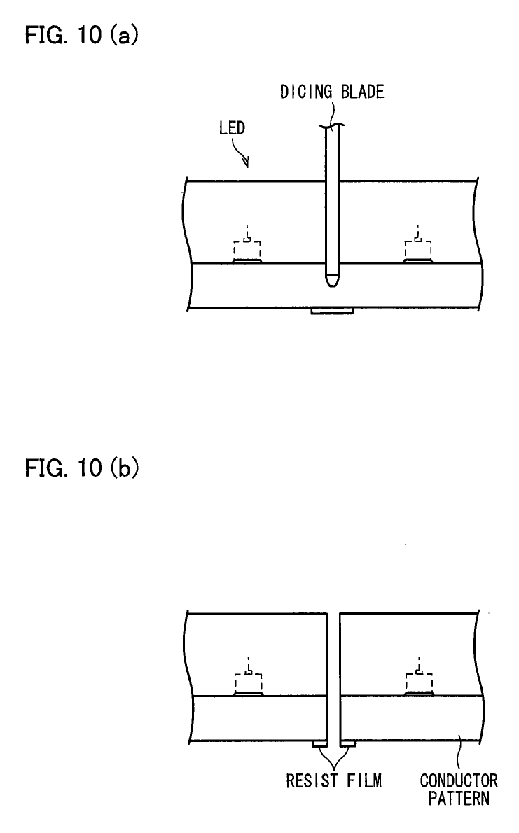

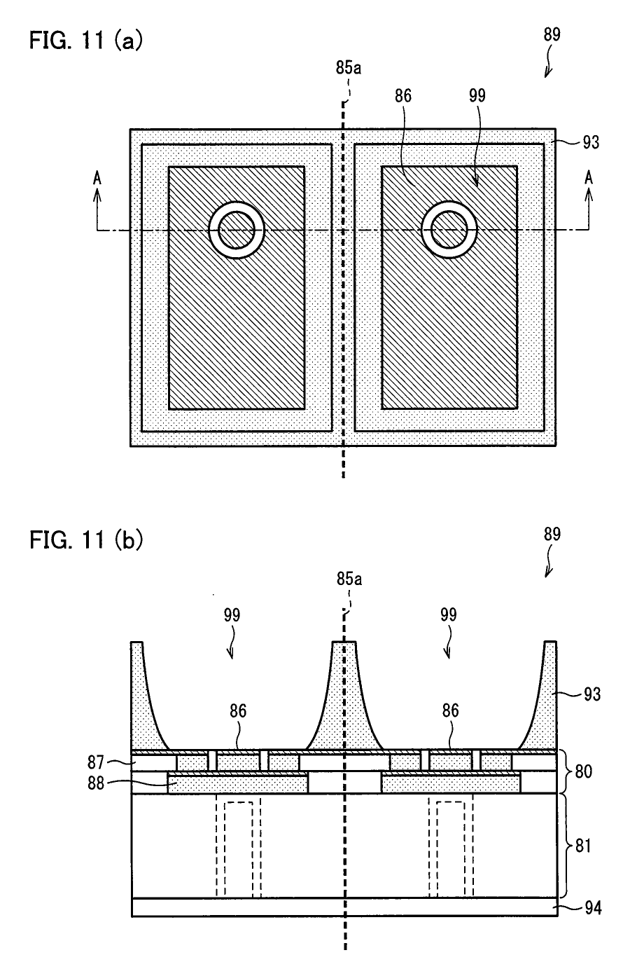

FIGS. 6(a) to 6(c) are cross sectional views for describing another method for cutting the multilayer substrate. FIG. 7 is a cross sectional view, showing a configuration of a light emitting device 1b manufactured in the above cutting method of the multilayer substrate. At first, as shown in FIG. 6(a), the electrocast blade 6d cuts the multilayer substrate 2 into certain depth from the backside electrode 4 so as to form a cutting trench 5d. Then, as shown in FIG. 6(b), the light emitting device material is inverted, and the adhesive sheet 20 is applied to the backside electrode 4. Next, an electrocast blade 6e, which is thinner than the electrocast blade 6d, cuts from the metal layer 3 to the adhesive sheet 20 through the multilayer substrate 2, and forms a cutting trench 5e so as to manufacture the light emitting device 1b shown in FIG. 7. Width dimension W2 of the light emitting device 1b is from 3 mm to 5 mm, for example.

As shown in FIG. 6(b), when the electrocast blade 6e cuts to the adhesive sheet 20, clogging of the electrocast blade 6e is removed due to the dressing effects of the adhesive sheet 20. As a consequence, the electrocast blade 6e can cut the light emitting device material with less electric power consumption as compared to a case where the electrocast blade does not cut to the adhesive sheet 20.

If the blade cuts along the dashed lines 15a shown in FIG. 1, burrs are caused, towards rotation directions of the blade, on cross sections of the metal layer 3 along the dashed lines 15a. If supersonic wave is applied to the blade, along a radius direction of the blade, the blade contracts to the radius direction and water can penetrate into a gap caused thereby. Thus, burrs can be prevented.

A step 8c is formed on the cross section of the multilayer substrate 2 between the cutting trench 5d and the cutting trench 5e. Like this, the cutting trench 5d is formed over the backside electrode 4 and the multilayer substrate 2 while the cutting trench 5e is formed over the metal layer 3 and the multilayer substrate 2. Width of the cutting trench 5d is wider than width of the cutting trench 5e.

The metal layer 3 of the light emitting device 1b manufactured in the above manner does not have either anode potential or cathode potential of the LED chip (not illustrated), hence has zero potential, the chip provided in the recess section 9. The light emitting device 1b is implemented on its cross section to the reflective sheet of the backlight device. Since the step 8c is formed on a cross section, as shown in FIG. 7, the cross section of the metal layer 3 (metal reflector) touches the implementing surface of the reflective sheet. Thus, heat generated from the LED (not illustrated) provided in the metal reflector can be released excellently; therefore, good heat radiation can be attained.

It is possible to configure the backlight device having the light emitting device 1a shown in FIGS. 4 and 5 or the light emitting device 1b shown in FIG. 7. The backlight device includes the light emitting device 1a, the reflective sheet to which the light emitting device 1a is implemented on the cross section of the multilayer substrate 2 provided to the light emitting device 1a, and an optical waveguide which irradiates a liquid crystal panel with light emitted from the light emitting device 1a, by scattering the light.

The backlight device preferably includes the light emitting device 1b, the reflective sheet to which the light emitting device 1b is implemented on the cross section of the metal layer 3 provided to the light emitting device 1b, and the optical waveguide.

Present embodiment can be used for the method for cutting the multilayer substrate having the first metal layer on the front surface and the second metal layer on the back surface, the method for manufacturing the semiconductor device equipped with this multilayer substrate, the semiconductor device, the light emitting device, and the backlight device.

The cutting method according to the present embodiment for cutting the multilayer substrate is preferably arranged such that width of the kerf on the second metal layer side is wider than width of the kerf on the first metal layer side.

According to the above configuration, the first metal layer is uncharged and the cross section thereof touches the substrate by being implemented, on the cross section of the multilayer substrate, to the substrate. Therefore, heat generated from the light emitting elements provided in the cup-shaped recess sections formed in the first metal layer can be released suitably from the first metal layer via the substrate.

The cutting method of according to present embodiment for cutting the multilayer substrate is preferably arranged such that width of the kerf from the second metal layer side is narrower than width of the kerf from the first metal layer side.

According to the above configuration, since the first metal layer is implemented, on its cross section, to the substrate, the gap is created between the cross section of the first metal layer and the substrate. Therefore, it is possible to make the first metal layer charged.

The cutting method of according to the present embodiment for cutting the multilayer substrate preferably cuts the multilayer substrate such that narrower one of the kerfs is positioned within the wider one of the kerfs.

According to the above configuration, it is possible to reliably control the forms of the steps on the cross sections of the multilayer substrate, the first metal layer, and the second metal layer. In addition, of the cross sections of the multilayer substrate, the first metal layer, and the second metal layer, width between the cross sections facing each other at higher steps is a package size which is required of accuracy stipulated by a standard. On the other hand, the cutting method according to the present embodiment is arranged such that cross sections at higher steps are always positioned to either the front surface side or to the back surface side of the multilayer substrate: therefore, it is possible to keep the package size within the accuracy of a cutting pitch of the dicing device which is highly accurately controllable.

The cutting method according to the present embodiment for cutting the multilayer substrate is preferably arranged such that width of the kerf for being cut later is narrower than the width of the kerfs for being cut earlier.

According to the above configuration, it is possible to cut the multilayer substrate stably.

The cutting method according to the present embodiment for cutting the multilayer substrate is preferably arranged such that the interface between the first metal layer and the multilayer substrate is cut from the first metal layer side while the interface between the second metal layer and the multilayer substrate is cut from the second metal layer side.

According to the above configuration, it is possible to prevent generation of burrs on the cross sections.

The cutting method according to the present embodiment for cutting the multilayer substrate is preferably arranged such that the first metal layer is thicker than the second metal layer.

According to the above configuration, it is possible to configure the light emitting device in which the cup-shaped recess sections are formed in the first metal layer and light emitting elements are provided in the recess sections.

The cutting method according to the present embodiment for cutting the multilayer substrate is preferably arranged such that the first metal layer is cut off with the cemented carbide blade.

According to the above configuration, it is possible to cut off the metal layer suitably with the cemented carbide blade.

The cutting method according to the present embodiment for cutting the multilayer substrate is preferably arranged such that the cemented carbide blade cuts off the metal layer while supersonic wave is being applied to the blade along its radius direction.

According to the above configuration, the blade contracts along the radius direction, and water can penetrate into the gap with the trench; therefore, it is possible to prevent the clogging of the rim of the blade.

The cutting method according to the present embodiment for cutting the multilayer substrate is preferably arranged such that multilayer substrate includes layers of different types of materials.

According to the above configuration, it is possible to configure the light emitting device in which second metal layer is the backside electrode while the cup-shaped recess sections are formed in the first metal layer, and the light emitting elements are implemented in the recess sections.

The cutting method according to the present embodiment for cutting the multilayer substrate is preferably configured such that the multilayer substrate includes the glass epoxy-substrate.

According to the above configuration, it is possible to configure the light emitting device in which the second metal layer is the backside electrode while the cup-shaped recess sections are formed in the first metal layer, and the light emitting elements are implemented in the recess sections.

The cutting method according to the present embodiment for cutting the multilayer substrate is preferably arranged such that the multilayer substrate includes the multilayer wiring resin layer.

According to the above configuration, it is possible to configure the light emitting device in which the second metal layer is the backside electrode while the cup-shaped recess sections are formed in the first metal layer, and the light emitting elements are implemented in the recess sections.

The cutting method according to the present embodiment for cutting the multilayer substrate is preferably arranged such that the step of cutting the multilayer substrate includes the steps of: forming the first cutting trench by cutting the first metal layer and the multilayer substrate into certain depth from the first metal layer side into the multilayer substrate but not to reach the second metal layer; and forming the second cutting trench reaching from the second metal layer side to the first cutting trench, and the step of forming the first cutting trench includes the step of cutting, with the cemented carbide blade, the first metal layer to right before the multilayer substrate.

According to the above configuration, the first metal layer can be cut suitably since it is cut with the cemented carbide blade while the multilayer substrate can be cut without being damaged even if it is composed of resin layers, since the multilayer substrate can be cut with the electrocast blade.

The cutting method according to the present embodiment for cutting the multilayer substrate is preferably configured such that the step of cutting multilayer substrate includes the steps of: forming the first cutting trench by cutting the second metal layer and the multilayer substrate into certain depth from the second metal layer side into the multilayer substrate but not to reach the first metal layer; and forming the second cutting trench reaching to the second cutting trench from the first metal layer side, and the step of forming the second cutting trench forms the second trench by the blade cutting through the adhesive sheet applied on the second metal layer.

According to the above configuration, since the blade cuts the multilayer substrate as cutting the adhesive sheet, the cutting efficiency is enhanced due to the dressing effects where the adhesive sheet removes the clogging of the blade caused by the cut scraps.

The light emitting device according to the present embodiment is preferably configured such that the first metal layer has a step on its side surface, the step being adjacent to the multilayer substrate.

According to the above configuration, it is possible to cut off the first metal layer with the cemented carbide blade and to cut off the multilayer substrate with the electrocast blade.

The present invention is not limited to the description of the embodiments above, but may be altered by a skilled person within the scope of the claims. An embodiment based on a proper combination of technical means disclosed in different embodiments is encompassed in the technical scope of the present invention.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A method for cutting a multilayer substrate having a first metal layer on a front surface and a second metal layer on a back surface, comprising the step of:
cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer,
width of a kerf on the first metal layer side and width of a kerf on the second metal layer side being different from each other.

2. The method for cutting the multilayer substrate as set forth in claim 1, wherein the width of the kerf on the second metal layer side is narrower than the width of the kerf on the first metal layer side.

3. The method for cutting the multilayer substrate as set forth in claim 1, wherein the width of the kerf on the second metal layer side is wider than the width of the kerf on the first metal layer side.

4. The method for cutting the multilayer substrate as set forth in claim 1, wherein the step of cutting the multilayer substrate is carried out such that narrower one of the kerfs is positioned within wider one of the kerfs.

5. The method for cutting the multilayer substrate as set forth in claim 1, wherein the width of the kerf for being cut later is narrower than the width of the kerf for being cut earlier.

6. The method for cutting the multilayer substrate as set forth in claim 1, wherein:
an interface between the first metal layer and the multilayer substrate is cut from the first metal layer side; and
an interface between the second metal layer and the multilayer substrate is cut from the second metal layer side.

7. The method for cutting the multilayer substrate as set forth in claim 1, wherein the first metal layer is thicker than the second metal layer.

8. The method for cutting the multilayer substrate as set forth in claim 1, wherein the first metal layer is cut off with a cemented carbide blade.

9. The method for cutting the multilayer substrate as set forth in claim 8, wherein the cemented carbide blade cuts off the multilayer substrate, while supersonic wave is being applied to the blade along a radius direction of the blade.

10. The method for cutting the multilayer substrate as set forth in claim 1, wherein the multilayer substrate includes layers of different types of materials.

11. The method for cutting the multilayer substrate as set forth in claim 1, wherein the multilayer substrate includes a glass epoxy-substrate.

12. The method for cutting the multilayer substrate as set forth in claim 1, wherein the multilayer substrate includes a multilayer wiring resin layer.

13. The method for cutting the multilayer substrate as set forth in claim 1, wherein the step of cutting the multilayer substrate includes the steps of:
forming a first cutting trench by cutting the first metal layer and the multilayer substrate into certain depth from the first metal layer side into the multilayer substrate but not to reach the second metal layer; and
forming a second cutting trench reaching from the second metal layer side to the first cutting trench,
the step of forming the first cutting trench including the step of cutting the first metal layer, with a cemented carbide blade, to right before the multilayer substrate.

14. The method for cutting the multilayer substrate as set forth in claim 1, wherein the step of cutting the multilayer substrate includes the steps of:
forming a first metal cutting trench by cutting the second metal layer and the multilayer substrate into certain depth from the second metal layer side into the multilayer substrate but not to reach the first metal layer; and
forming a second cutting trench reaching from the first metal layer side to the first cutting trench,
the step of forming the second cutting trench forming the second cutting trench by a blade cutting through an adhesive sheet applied on the second metal layer.

15. A method for manufacturing a semiconductor device including a multilayer substrate having a first metal layer on a front surface and a second metal layer on a back surface, comprising the step of
cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer,
width of a kerf on the first metal layer side and width of a kerf on the second metal layer side being different from each other.

16. A semiconductor device manufactured by a method for manufacturing a semiconductor equipped with a multilayer substrate having a first metal layer on a front surface and a second metal layer on a back surface,
the method including the step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer,
width of a kerf on the first metal layer side and width of a kerf on the second metal layer side being different from each other.

17. A light emitting device including a multilayer substrate having a first metal layer on a front surface and a second metal layer on a back surface, the first metal layer having a cup-shaped recess section in which a light emitting element is provided, and the light emitting device being manufactured by a method including cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, width of a kerf on the first metal layer side and width of a kerf on the second metal layer side being different from each other, wherein:
the multilayer substrate has a side surface on which the kerf on the first metal layer side and the kerf on the second metal layer side meet each other and on which a step is formed where the kerfs meet each other.

18. The light emitting device as set forth in claim 17, wherein the first metal layer has a step on its side surface, the step being adjacent to the multilayer substrate.

19. A back light device, comprising:
a light emitting device including a multilayer substrate having a first metal layer on a front surface and a second metal layer on a back surface, the first metal layer having a cup-shaped recess section in which a light emitting element is provided, and the light emitting device being manufactured by a method including the step of cutting the first metal layer and the multilayer substrate into certain depth respectively from a first metal layer side into the multilayer substrate but not to reach the second metal layer, and the second metal layer and the multiplayer substrate from a second metal layer side into the multilayer substrate but not to reach the first metal layer, width of a kerf on the first metal layer side and width of a kerf on the second metal layer side being different from each other, the multilayer substrate having a side surface on which the kerf on the first metal layer side and the kerf on the second metal layer side meet each other and on which a step is formed where the kerfs meet each other;
a reflective sheet to which the light emitting device is implemented in such a manner that the side surface of the multilayer substrate of the light emitting device attaches with the reflective sheet; and
an optical waveguide for irradiating a liquid crystal panel with light from the light emitting device, by scattering the light.
